(19) United States
(12) Patent Application Publication
(10) Pub. No.: US 2003/0155655 A1
(43) Pub. Date: Aug. 21, 2003

(54) Integrated, active, moisture and oxygen getter layers

(75) Inventors: John A. Fitzsimmons, Poughkeepsie, NY (US); Stephen M. Gates, Ossining, NY (US); Vincent J. McGahay, Poughkeepsie, NY (US)

Correspondence Address: Graham S. Jones, II, 42 Barnard Avenue, Poughkeepsie, NY, 12601-5023, US

(73) Assignee: International Business Machines Corporation, Armonk, NY

(21) Appl. No.: 10/078,875

(22) Filed: Feb. 20, 2002

(51) Int. Cl. H01L 23/48; H01L 23/52; H01L 29/40

(52) U.S. Cl. 257/774

(57) ABSTRACT

An integrated circuit structure comprises a main dielectric layer having a top surface. A cavity having sidewalls is formed in the main dielectric layer. A liner is formed on the sidewalls of the cavity. A metal conductor such as copper is formed over the liner filling the lined cavity. A getter layer is formed in the structure which combines with oxygen/moisture to form inert reaction products thereof. The getter layer can be either a conductive material which can be included in the liner or a dielectric layer which can be formed on top of the main dielectric layer, buried in the main dielectric layer or below the main dielectric layer.

### BACKGROUND OF THE INVENTION

1. Field of the Invention

This invention relates to interconnect structures for VLSI and ULSI semiconductor devices such as high speed microprocessors, Application Specific Integrated Circuits (ASICs), and other high speed IC's (Integrated Circuits).

2. Description of Related Art

Many advanced semiconductor devices such as semiconductor chips are extremely susceptible to degradation due to the effects of oxygen and moisture. The term “moisture” is defined herein to include water (H₂O) in the form of molecules of water, droplets of water, water vapor and the like. To solve the problem of degradation due to the effects of oxygen and moisture, the common approach in industry is to encapsulate advanced semiconductor devices to limit ingress of these contaminants into the devices. That is to say that, in the past, the problems caused by moisture and/or oxygen have been addressed by sealing the package once the device processing is complete to prevent moisture and/or oxygen from entering the devices. Also previously, vacuum degassing steps have been used in attempts to lower the moisture and/or oxygen levels within the device package before the application of moisture and/or forming oxygen barriers to passivate the device. However, both of theses methods fail in that they leave some trace level of the moisture and/or oxygen contaminants which are often sealed inside the sealed package or encapsulated region acts to degrade the semiconductor devices. During prolonged chip operation, near 150° C. or during stress testing the moisture and/or oxygen may have several adverse effects on chip operation.

Heretofore, in low dielectric constant (“low-k”)+Cu (copper) BEOL (Back-End-Of-Line) interconnects, moisture and/or oxygen are typically trapped within the dielectric during processing, and it is difficult or impossible to avoid the presence of trace amounts of moisture and/or oxygen inside the completed device such as a chip. Also, moisture and/or water or oxygen may enter the chip when defects (cracks) are formed/propagated in the chip passivation during packaging operations.

The harmful effects of moisture and/or oxygen can include as follows:

a) damaging oxidation of metal wiring structures, supporting hydration of ionic contamination leading to enhanced conduction, and

b) damaging reactions with insulator structures leading to decreased effectiveness of their original ability to produce the desired effects.

Traditionally gettering has been used to remove unwanted gases from electron tubes and the like has involved use of gettering. Getter pumps have been used in which gettering agents are continuously depositing a sorbent (gettering agent) in the operation of a gettering pump.

Hong et al. U.S. Pat. No. 5,753,560 entitled “Method for Fabricating Semiconductor Device Using Lateral Gettering” describes forming doped regions referred to as gettering sinks in a silicon layer. Lateral gettering removes impurities from the central area by gettering impurities into locations withing the silicon layer which are laterally spaced well away from the center of a MOSFET device to the sides of the source region and the drain region. The gettering agents are ion implanted elements selected from silicon, germanium, carbon, tin, lead, nitrogen, fluorine, hydrogen, helium, neon, argon, krypton and xenon. In addition, boron penetrating the gate oxide in pMOS devices was dealt with by growing a thin film of polyoxide over a polysilicon gate electrode in oxygen gas at 900° C. for ten minutes .

Lin et al. “Thin Polyoxide on the Top of Poly-Si Gate to Suppress Boron Penetration for pMOS” IEEE Electron Device Letters, VOL. 16, No. 5, (May. 1995) pages 164-165 describes gettering of fluorine gate with a thin oxide. “This thin oxide will getter the fluoride out of the poly-Si gate, hence reduce the amount of fluorine in the poly-Si as well as the gate oxide.” Later the polyoxide was removed from the poly-Si and aluminum was deposited to form a capacitor.

In the past conductive liner layers have been employed between interconnect conductors and the dielectric layers surrounding the conductors in structures including damascene structures, but none of the interconnects have included gettering agents for removing impurities in general or moisture or oxygen in particular.

R. Goldblatt et al. “A High Performance 0.13 μm Copper BEOL Technology with Low-k Dielectric”, Proceedings of IITC, IEEE Electron Devices Society, pages 261-263, June 2000″ describes integration of dual damascene copper metallization in a spin-on inter metal dielectric (e.g SiLK™ semiconductor dielectric, the Dow Chemical Co. which is an aromatic hydrocarbon thermosetting polymer). The liner/seed deposition and copper plating process employed in dual damascene processing.

U.S. Pat. No. 6,291,885 of Cabral et al. for “Thin Metal Barrier for Electrical Interconnections” shows a conductor (composed of copper, copper alloys, aluminum, alloys of aluminum, tungsten and PbSn) which is to be separated from a dielectric (composed glass, spin on glass, silicon nitride polyimide, carbon, etc.) by a liner composed of TaN in the hexagonal phase, plus a Ta layer in the alpha phase adjacent to the TaN layer.

Edelstein et al. “An Optimal Liner for Copper Damascene Interconnects” “Proceedings of Advanced Metallization Conference (AMC) October 9-11, Montreal Canada describes use of a bilayer liner of hcc/fcc-TaN followed by bcc-Ta.

U.S. Pat. No. 6,140,226 of Grill et al. for “Dual Damascene Processing for Semiconductor Chip Interconnects” shows how to form a dual relief cavity and then the cavity “is optionally lined with one or more adhesion or diffusion barrier layers (not shown) and then overfilled with conductive wiring material . . . by a process such as physical vapor deposition, chemical vapor deposition, solution deposition, or plating . . . Conductive wiring material . . . is then planarized by a process such as chemical mechanical polishing to be approximately even with the top surface of dielectric . . . and/or remaining hard mask . . . Remaining hard mask . . . is then removed . . . ”

Other low-k dielectric plus Cu (copper) interconnect structures and methods for making the structures are known. An example of a dual damascene type of structure based on an organic thermoset dielectric is described in Goldblatt et aL, supra. One type of appropriate dielectric is an organic thermoset dielectric, e.g. a spin-on inter metal dielectric (e.g SiLK™ semiconductor dielectric, the Dow Chemical Co.).

### SUMMARY OF THE INVENTION

The present invention is based upon the general strategy of removing moisture and/or oxygen trapped in a device by gettering, i.e. permanently reacting a suitable reactive layer (i.e. getter) with the moisture and/or with the oxygen. Accordingly, an internal getter layer for removing contaminants in the form of moisture and/or oxygen from regions where they can cause damage is included inside the structure within the encapsulated package to react with the contaminants so that they are unavailable to degrade the semiconductor device.

In accordance with this invention, an integrated circuit structure comprises a main dielectric layer having a top surface. A cavity having sidewalls is formed in the main dielectric layer. A liner is formed on the sidewalls of the cavity. A metal conductor such as copper is formed over the liner filling the lined cavity. A getter layer is formed in the structure which combines with oxygen/moisture to form inert reaction products thereof. The getter layer can be either a conductive material which can be included in the liner or a dielectric layer which can be formed on top of the main dielectric layer, buried in the main dielectric layer or below the main dielectric layer.

An object of this invention is to provide a structural means adapted for removal of moisture and/or oxygen contaminants which are often sealed within the semiconductor structure during the production process. These contaminants are known to have deleterious effects on semiconductor devices (e.g. decreased reliability) and thus the present invention will serve to mitigate the cause of these deleterious reactions, consequently improving the reliability of the semiconductor device.

Another an object of this invention to locate an active getter layer as part of the hard mask, which is deposited on the organic thermoset dielectric.

It is another object of this invention to locate an active getter layer as part of the conductive metallic liner surrounding each metal conductor or interconnect feature which is preferably composed of copper.

Still another object of this invention to locate an active getter layer embedded within the “post-CMP Cap” which is deposited directly on a metal conductor line or interconnect feature which is preferably composed of copper.

Another object of the invention is a structure adapted for removing moisture and/or oxygen from the low k dielectric before the moisture and/or oxygen has a degradative effect.

### BRIEF DESCRIPTION OF THE DRAWINGS

The foregoing and other aspects and advantages of this invention are explained and described below with reference to the accompanying drawings, in which:

FIG. 1A is a cross sectional, elevational view illustrating a first embodiment of the present invention in an integrated circuit design wherein a gettering layer is incorporated within the metallic liner structure formed surrounding a conductor/interconnect in a semiconductor device.

FIGS. 1B and 1C are enlarged sectional views of the lower left corner of the device of FIG. 1A showing a portion of the metallic liner structure, the metallic conductor and the main dielectric layer.

FIG. 2A shows a cross sectional, elevational view of a second embodiment of the present invention illustrating a pair of dual damascene metal conductor lines, formed as shown in FIG. 1A with the provision of a dielectric-getter layer incorporated onto the surface of the main dielectric layer as a part of the insulator structure of a semiconductor device. The insulator structure incorporates an oxygen/moisture gettering layer on the surface of the dielectric of a semiconductor device and another gettering layer also surrounding the conductor/interconnect in a semiconductor device.

FIGS. 2B, 2C and 2D are enlarged sectional views of the lower left corner of the device of FIG. 2A showing a portion of the metallic liner structure, the metallic conductor and the main dielectric layer.

FIG. 3A is a cross sectional, elevational view of a second embodiment of the present invention illustrating the present invention with a gettering layer incorporated as a buried insulator level within the main dielectric and another gettering layer also surrounding the conductor/interconnect in a semiconductor device.

FIGS. 3B, 3C, and 3D are enlarged sectional view of the lower left corner of the device of FIG. 3A showing a portion of the metallic liner structure, the metallic conductor and the main dielectric layer.

FIGS. 4A-4D illustrate a modification of the embodiment of the present invention shown in FIGS. 3A-3D wherein the device includes vias (composed of a conductive metal) which are formed generally below the top surface of the buried insulator-getter layer.

FIG. 5A is a cross sectional, elevational view of a second embodiment of the present invention which illustrates the use of a sub-main insulator getter structure deep within the main dielectric and also another gettering layer surrounding the conductor/interconnect in a semiconductor device.

FIGS. 5B, 5C and 5D are enlarged sectional views of the lower left corner of the device of FIG. 5A showing a portion of the metallic liner structure, the metallic conductor and the main dielectric layer.

### DESCRIPTION OF THE PREFERRED EMBODIMENT

The present invention is based upon the general strategy of removing moisture and/or oxygen trapped in a device by gettering, i.e. permanently reacting a suitable reactive layer (i.e. getter) with the moisture and/or with the oxygen. Accordingly, a getter layer is included inside the encapsulated package to react with the contaminants so that they are unavailable to degrade the semiconductor device.

The present invention is embodied in four different locations of gettering layers which are either composed of conductive getters or dielectric getters, whichever is appropriate. One application of this strategy is to place conductive, active getter layers integrated within the BEOL interconnect structure. Each structure includes a getter layer which comprises an, oxygen/moisture absorbing, layer placed in a different location in a device comprising BEOL low dielectric constant (low k) interconnect.

During and after the manufacturing process, the gettering layers are present for the purpose of removing harmful contaminants from the BEOL interconnect structure, preventing reaction of the contaminating moisture and/or oxygen with the sensitive device structures, e.g. metal conductor lines, or other parts of the chip. The inventive getter layer can be integrated at many locations within a chip or other semiconductor device. While the conductor lines are preferably composed of copper, alternative metals include aluminum, gold, platinum, silver and the like.

An alternative approach is to form a dielectric gettering material in the structure that forms a stable compound within the dielectric that is also inert when the getter reacts with moisture and/or oxygen (or is oxidized).

One way to accomplish the removal of the moisture and/or oxygen from interconnect structures and other portions of semiconductor devices with a dielectric getter material is to provide getter layers of amorphous hydrogenated silicon carbide (a-SiCH) within the semiconductor structure to remove moisture and oxygen by reaction to form a stable compound that is inert (i.e. oxidized amorphous hydrogenated silicon carbide (a-SiCH) to the semiconductor operation and structure and removes these harmful contaminants from reacting with the sensitive device structures, e.g. metal conductor lines which preferably comprise copper lines.

As described above, the getter layer removes moisture and oxygen and the negative effects they can induce, including the oxidation of sensitive structures (e.g. metal lines and vias) to prevent the degradation of the semiconductor device.

The key attributes of the inventive getter film are that the getter layer must react with moisture, water, water vapor, and oxygen.

The reaction of the getter layer with oxygen and/or moisture must be irreversible under the operating conditions of the device, i.e. once the moisture has reacted, it is not released, thus, it is removed (i.e. sequestered and isolated so that there is no possibility of oxygen and/or moisture reacting with other films within the device. This reaction must not produce a product that causes undue strain on the device/package (i.e. there should be little if any volume expansion, the product should not degrade the established interfaces.)

This reaction product is itself can be an insulator, unless an electrically conductive getter is implemented in such a manner that electrical conductivity of the getter layer is not significant within the integration scheme or is a required feature of the portion of the device being protected from moisture and/or oxygen.

The reaction of the getter layer with moisture and/or oxygen must not produce mobile by products which are detrimental to the device, i.e. there should not be the production of byproducts, e.g. hydrogen fluoride (HF).

There are several ways the invention may be implemented.

In one embodiment, a preferred aspect of the invention is that the getter layer will not react with moisture at ambient conditions and is activated for reaction at either subsequent thermal cycling or during the operation conditions of the working semiconductor device. Examples of materials that meet these requirements are amorphous hydrogenated silicon carbide (a-SiCH) alloys, amorphous hydrogenated silicon (a-SiH), and amorphous hydrogenated germanium (a-GeH).

As preferred example, an amorphous alloy of Si, C, and H that contains a high concentration of SiH₂ bonding provides a preferred material.

In a second embodiment of the invention, where appropriate the getter layer may comprise a reactive metal e.g. Ti, Cr, Al, V, Zr, Hf, and In, or the like.

Four exemplary embodiments are described herein, with the getter placed in different locations within the BEOL interconnect structure. These examples will make it be evident to one skilled in the art that the getter layers of this invention may be placed in other locations (in the BEOL interconnect structure) within the present invention.

Briefly, these four embodiments place the inventive getter in as follows:

### Method 1

The getter layer or film may be located with a “hard mask” between the Chemical Mechanical Polishing (CMP) polish-stop and the low-k, main dielectric. In a CMOS integration scheme the getter layer could be an amorphous hydrogenated silicon (a-SiH) layer applied upon a main dielectric layer (e.g. SiLK™ dielectric) just before the application of the silicon nitride hard mask. Optimum performance would be achieved if the silicon nitride hard mask remained intact during the subsequent liner Chemical Mechanical Polishing (CMP) step.

### Method 2

A metal getter film is deposited so that it is in a highly reactive state in order to maximize the gettering action of the gettering metal. One such method of deposition is to use very highly pure elemental metal deposition, without any lattice structure or reactive impurities during the deposition. Locate a reactive metal getter film composed of Ti, Cr, Al, V, Zr, Hf, and In, or the like within the “liner” as the first layer of a bilayer structure. Cover the reactive first layer with a second less reactive layer of Ta, W, or Nb or a similar metal. Note that in this embodiment the getter may be a conductive material. Thus the composition of the getter layer is not restricted to insulator type materials.

### Method 3

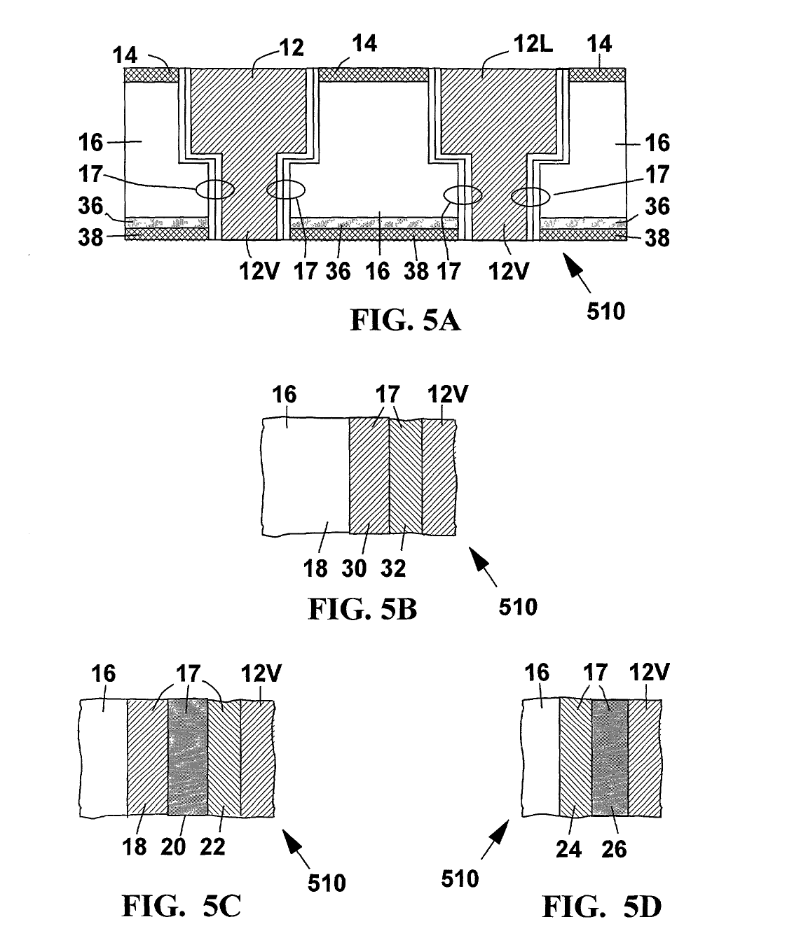

After forming a post-Chemical Mechanical Polishing (CMP) Cap, locate a getter film as a second film atop a first Cu (copper) barrier film, thus forming a bilayer cap with distributed functions such as Cu (copper) barrier function in the first layer and getter function in the second film. Note that in this embodiment the getter layer may be applied directly subsequent to the application of an insulator layer directly in contact with the copper wiring level. This is illustrated in FIG. 5A where layer 38 is a copper barrier layer and layer 36 is a getter dielectric layer, as described in detail below.

### Method 4

This is similar to the application in Method 3 above. However, the application of the getter layer is not restricted to a directly subsequent application, in that, the getter layer may be placed at any point within the main dielectric layer. For example the getter layer may be placed together with a buried hard mask in a laminated combination. It should be understood that the hard mask and getter areas can be separate functions that can be combined or separated as a matter of design choice.

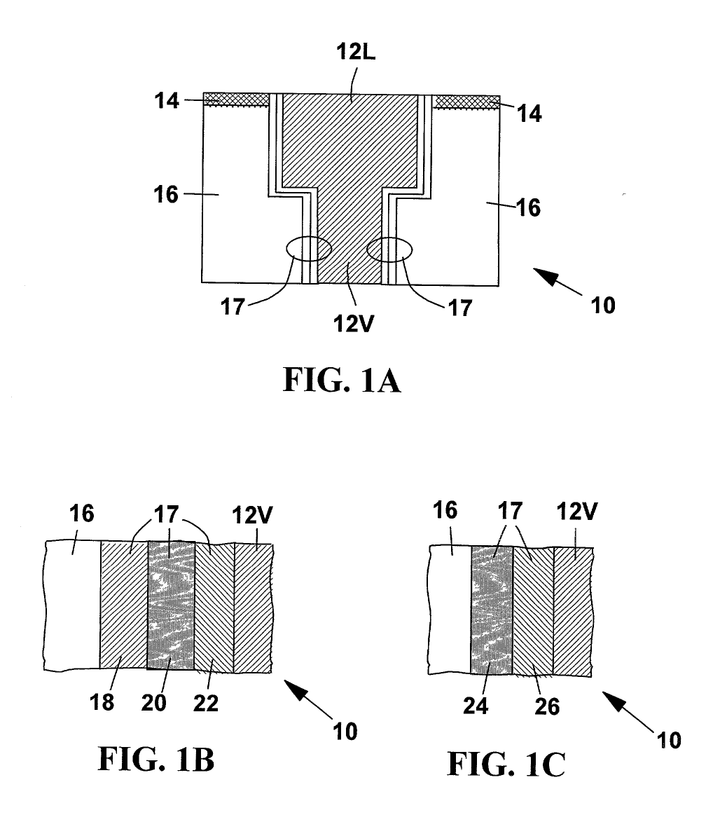

FIG. 1A is a cross sectional, elevational view illustrating a first embodiment of the present invention in an integrated circuit design wherein a gettering layer is incorporated within the metallic liner structure formed surrounding a conductor/interconnect in a semiconductor device. FIGS. 1B and 1C are enlarged sectional views of a fragment of the lower left corner of the device of FIG. 1A showing a portion of the metallic liner structure, the metallic conductor and the main dielectric layer.

Referring to FIG. 1A, a device 10 includes a main dielectric layer 16 in which a dual relief cavity has been formed and then lined with a laminated liner 17 covering the sidewalls of the dual relief cavity. The laminated liner 17 has been filled with a dual damascene metal conductor line 12L and via 12V (composed of conductive metallic material) and the device has been planarized. The metal conductor line 12L and via 12V are separated from the main dielectric layer 16 by the laminated liner 17. The laminated liner 17 comprises a metallic diffusion barrier preferably 1 nm to 10 nm thick.

The dielectric layer 16 can be composed of any low k dielectric material e.g. SiLK™ polymer or a PECVD SiCOH (carbon doped oxide or OrganoSilicate Glass (OSG)) alloy. Examples of these SiCOH or OSG films include Black Diamond (available from Applied Materials) and Coral (available from Novellus), and other products. This invention may use any of various main dielectric materials, including but not limited to, fluorine-doped silicon oxide (called FluoroSilicate Glass (FSG)); spin-on glasses; SilsesQuioxanes, including Hydrogen SilsesQuioxane (HSQ), Methyl SilsesQuioxane (MSQ) and mixtures or copolymers of HSQ and MSQ; and any silicon-containing low-k dielectric. Examples of spin-on low-k films with SiCOH-type composition using SilsesQuioxane chemistry include HOSP™ (available from Honeywell), JSR 5109 and 5108 (available from Japan Synthetic Rubber), Zirkon™ (available from Shipley Microelectronics), and porous low k (ELk) materials (available from Applied Materials)

In FIGS. 1A-1C, the laminated liner 17 includes one or more adhesion or diffusion metallic barrier layers. The laminated liner 17 is juxtaposed with the metal conductor via 12V and the metal conductor line 12L.

In FIGS. 1B and 1C, the conductive getter layer 20/24 covers the exterior surface of the inner metallic liner layer 22/26.

As shown in FIG. 1A, a hard mask layer 14 covers the main dielectric layer 16, aside from the metal conductor line 12L, via 12V, and the laminated liner 17. The hard mask layer 14 may be composed of any one of several materials. Commonly SiNₓ, SiCH, or SiCOH alloys have been used as hard mask layers. In some embodiments of this invention, the structures shown may be formed without a hard mask layer 14, since the hard mask layer is only one preferred way to form structures employing the gettering features of this invention. As will be well understood by those skilled in the Very Large Scale Integrated (VLSI) circuit technology and Ultra Large Scale Integrated (ULSI) circuit technology, the substrate (not shown, e.g. a semiconductor chip) upon which the main dielectric layer 16 is formed, may contain electronic devices and other metal interconnect layers.

FIG. 1B is an enlarged sectional view of the lower left corner of FIG. 1A with laminated metallic liner layers 17 shown in FIG. 1A in which the metallic liner layers 17 serve as a metallic diffusion barrier which separates the metal conductor line 12L and via 12V on the right from the main dielectric layer 16, a fragment of which is shown on the left.

In the preferred embodiment in FIG. 1B, the metallic liner layers 17 comprises the getter layer 20 sandwiched between outer metallic liner layer 18 and inner metallic liner layer 22. The main dielectric layer 16 is on the left of the outer metallic liner layer 18; and the metal conductor line 12 on the right of the inner metallic liner layer 22.

While the outer and inner metallic liner layers 18/22 are illustrated as single films it is clearly understood that this is for convenience of illustration only and that for the purpose of the present invention, the inner and outer metallic liner layers 18/22 can be either multiple layers or single layers. The key feature of the embodiment shown in FIG. 1B is that the getter layer 20 is sandwiched between the metallic liner layers 18/22.

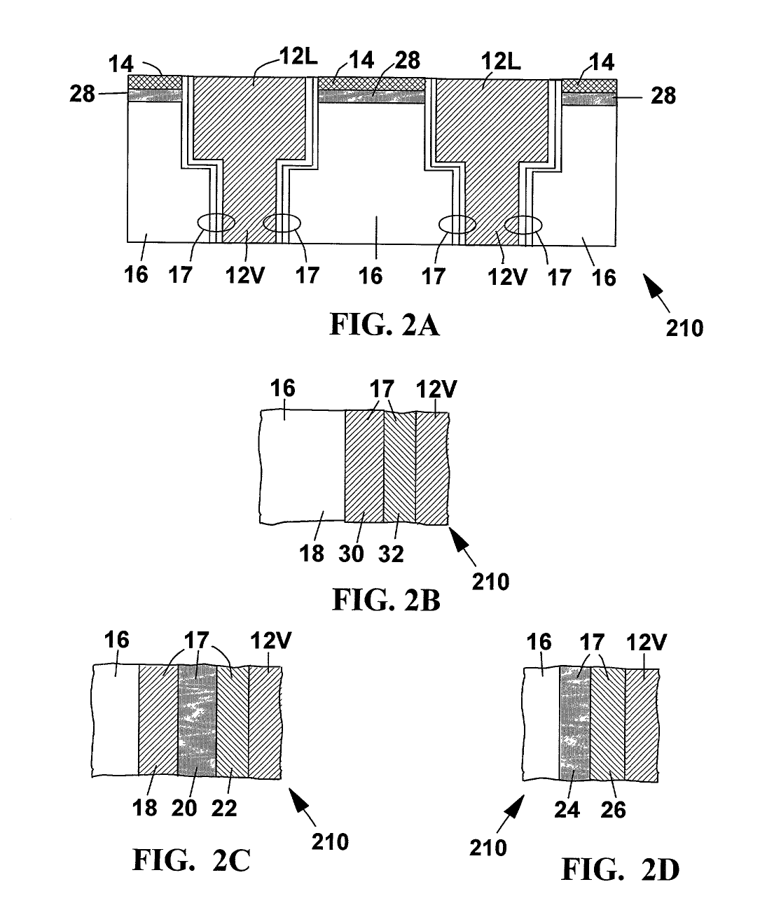

FIG. 1C is an expanded view of an alternative laminated layer 17 including only a getter layer 24 and an inner metallic liner layer 26 without an outer metallic liner layer. In the case of this less complicated laminated layer 17, the getter layer 24 is between the metallic liner 26 and the main dielectric layer 16 with the metallic liner layer adjacent to the metal conductor line 12L and via 12V. As in the case of FIG. 1B, it is immaterial whether the metallic liner layer 26 is a single layer or a composite structure. The key factor is that this getter layer 24 protects both the metal conductor metal line 12L and via 12V and insulator layer 16 from the deleterious effects of moisture and/or oxygen by the proximity of the getter layer 24 to both the insulator, i.e. the main dielectric layer 16, and the metal conductor metal line 12L and via 12V. FIGS. 2A-2C illustrate a pair of dual damascene metal conductor lines 12L and via 12V, preferably composed of copper, formed as shown in FIG. 1A with the provision of an additional getter layer 28 incorporated onto the surface of the main dielectric layer 16 as a part of the insulator structure of a semiconductor device 210. The main dielectric layer 16 may be composed of any of the materials listed with reference to FIG. 1. e.g. SiLK™ polymer or a PECVD SiCOH (carbon doped oxide or OrganoSilicate Glass (OSG)) alloy. Examples of these SiCOH or OSG films include Black Diamond (available from Applied Materials) and Coral (available from Novellus), and other products. This invention may use any of various main dielectric materials, including but not limited to, fluorine-doped silicon oxide (called FluoroSilicate Glass (FSG)); spin-on glasses; SilsesQuioxanes, including Hydrogen SilsesQuioxane (HSQ), Methyl SilsesQuioxane (MSQ) and mixtures or copolymers of HSQ and MSQ; and any silicon-containing low-k dielectric. Examples of spin-on low-k films with SiCOH-type composition using SilsesQuioxane chemistry include HOSP™ (available from Honeywell), JSR 5109 and 5108 (available from Japan Synthetic TS Rubber), Zirkon™ (available from Shipley Microelectronics), and porous low k (ELk) materials (available from Applied Materials).

FIG. 2A shows a laminated getter layer 28 as it is incorporated as a sub-hard mask layer between the hard mask layer 14 and the main dielectric layer 16 which is shown in detail in an enlarged view in FIG. 2D, as described below as well as metallic liner layers 17 of the kinds described above and as shown in FIGS. 2B and 2C which are enlarged views of the metallic liner layers 17. Here, the getter layer must be a dielectric, and a preferred material is amorphous hydrogenated silicon carbide (a-SiCH). FIGS. 2B-2D are expanded views of the lower left portion of FIG. 2A showing details of the metallic liner layers 17 between the main dielectric layer 16 and the metal conductor line 12L and the metal via 12V to demonstrate that multiple metallic liner layers 17 may be incorporated in a device which includes the dielectric sub-hard mask dielectric getter layer 28.

In the embodiment of FIG. 2B, the metallic liner layers 17 comprise only the outer metallic liner layer 30 and inner metallic liner layer 32. The main dielectric layer 16 is on the left of the outer metallic liner layer 18; and the metal conductor line 12 on the right of the inner metallic liner layer 22. Note that in the case of FIG. 2B neither the outer metallic liner layer 30 nor the inner metallic liner 32 is a getter layer. In this embodiment the only getter layer present is the sub-hard mask dielectric getter layer 28; whereas in FIG. 1B above, there was a getter layer 20 located between the inner metallic liner layer 22 and the outer metallic liner layer 18.

Alternatively, FIG. 2A can incorporate two getter layers including both the sub-hard mask dielectric getter layer 28 as shown in FIGS. 2B and 2C and a getter metallic liner composite structure.

In FIG. 2C the metallic liner composite structure 17 includes the getter layer 20 between the inner metallic liner layer 22 and the outer metallic liner layer 18 as in FIG. 1B.

In FIG. 2D the metallic liner composite structure includes the getter layer 24 between the inner metallic liner layer 26 and the main dielectric layer 16 as in FIG. 1C. The metal conductor lines 12L and metal conductor vias 12V are to the right of the inner metallic liner layer 26.

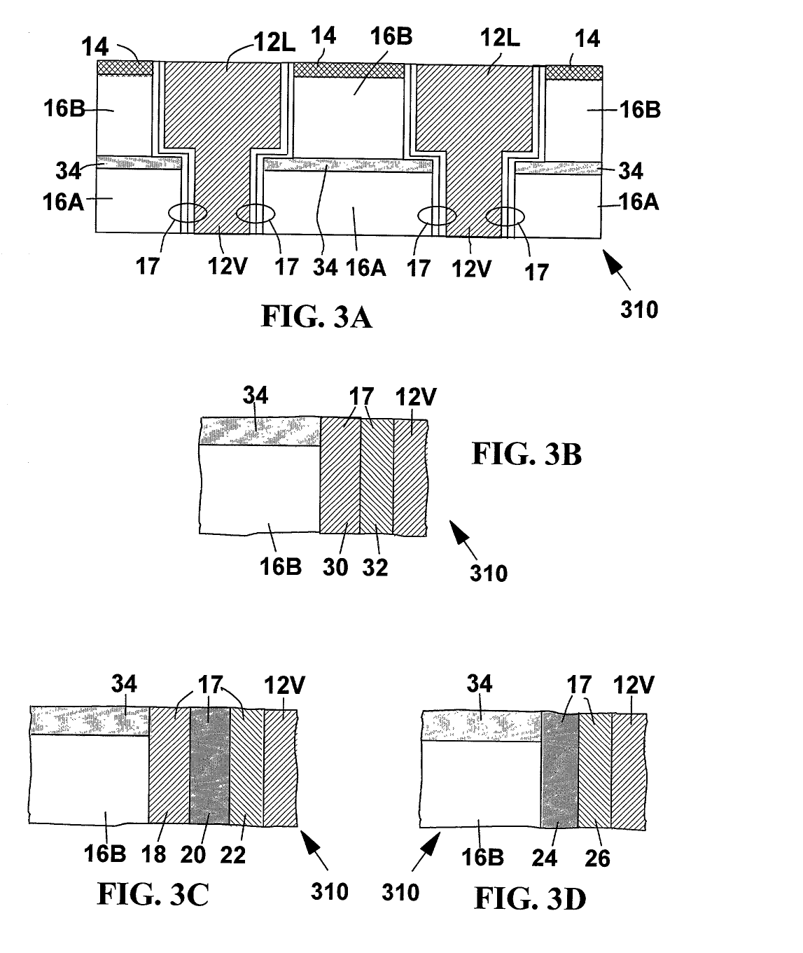

FIGS. 3A-3D shows an insulator structure of a semiconductor device 310 illustrating an embodiment of the present invention wherein the buried insulator-getter layer 34 is incorporated as a buried insulator 34 at a deep level within the main dielectric layer 16 which is composed of an upper main dielectric layer 16A and a lower main dielectric layer 16B. In this case the buried insulator-getter layer 34 is shown at the top of the lower (first) damascene level of the double damascene levels near the level of the tops of the metal conductor vias 12V.

FIG. 3A illustrates the use of the insulator-getter 34 as both a getter and a buried Reactive Ion Etching (RIE) etch stop. In this combination use the insulator-getter layer 34 is positioned at a height where the narrower metal conductor vias 12V transition into the wider conductors lines 12L in a damascene type of structure. This dual use serves both the purpose of the RIE etch stop and dielectric getter, and is shown in FIG. 3A.

FIGS. 3B-3D are expanded views of the lower left portion of FIG. 3A showing details of the metallic liner layers 17 between the main dielectric layer 16 and the metal conductor vias 12V to demonstrate that multiple metallic liner layers 17 may be incorporated in a device which includes the dielectric buried insulator-getter layer 34.

In the embodiment of FIG. 3B, the metallic liner layers 17 comprise the outer metallic liner layer 30 and inner metallic liner layer 32 without any getter layer. The lower main dielectric layer 16B is on the left of the outer metallic liner layer 30; and the metal conductor line 12 on the right of the inner metallic liner layer 32. Note that in the case of FIG. 2B neither the outer metallic liner layer 30 nor the inner metallic liner 32 is a getter layer. In this embodiment the only getter layer present is the sub-hard mask getter layer 28; whereas in FIG. 1B above, there was a getter layer 20 located between the inner metallic liner layer 22 and the outer metallic liner layer 18.

Optionally, this insulator-getter layer 34 may be located anywhere within the main dielectric, and the getter action is obtained. Thus, this buried insulator-getter layer 34 could be located anywhere within the main dielectric, however, if it were located at a position where the transition from via 12V to line 12L did not occur it would not be used as a buried RIE stop but as an insulator-getter only.

FIG. 3B is analogous to FIG. 2B in that it displays an expanded view of the metallic liner construction with an outer metallic liner 30 and an inner metallic liner 32 without any getter properties in contact with the buried insulator-getter layer 34.

FIGS. 3C and 3D are analogous to FIGS. 2C and 2D in that they illustrate that a buried insulator-getter layer 34 may be used in conjunction with the metallic liner composite structure which incorporates a getter layer.

In FIG. 3C the lower left of FIG. 3A is shown with the lower dielectric layer 16B covered by the buried insulator-getter layer 34 with the right side thereof in contact with the outer metallic liner layer 18 followed by the getter layer 20, followed with the inner metallic liner layer 22 for the increased getter effect; or the getter layer 24 and the inner metallic liner layer 26 in FIG. 3D.

In FIG. 3C the getter metallic liner composite structure includes the getter layer 20 between the inner metallic liner layer 22 and the outer metallic liner layer 18 as in FIG. 2C.

Alternatively, FIG. 3A can incorporate two getter layers including both the sub-hard mask getter layer 28 as shown in FIGS. 2B and 2C and a getter metallic liner composite structure.

In FIG. 3D the metallic liner composite structure includes the getter layer 24 between the inner metallic liner layer 26 and the main dielectric layer 16 as in FIG. 1C. The conductive metal via 12V is to the right of the inner metallic liner layer 26.

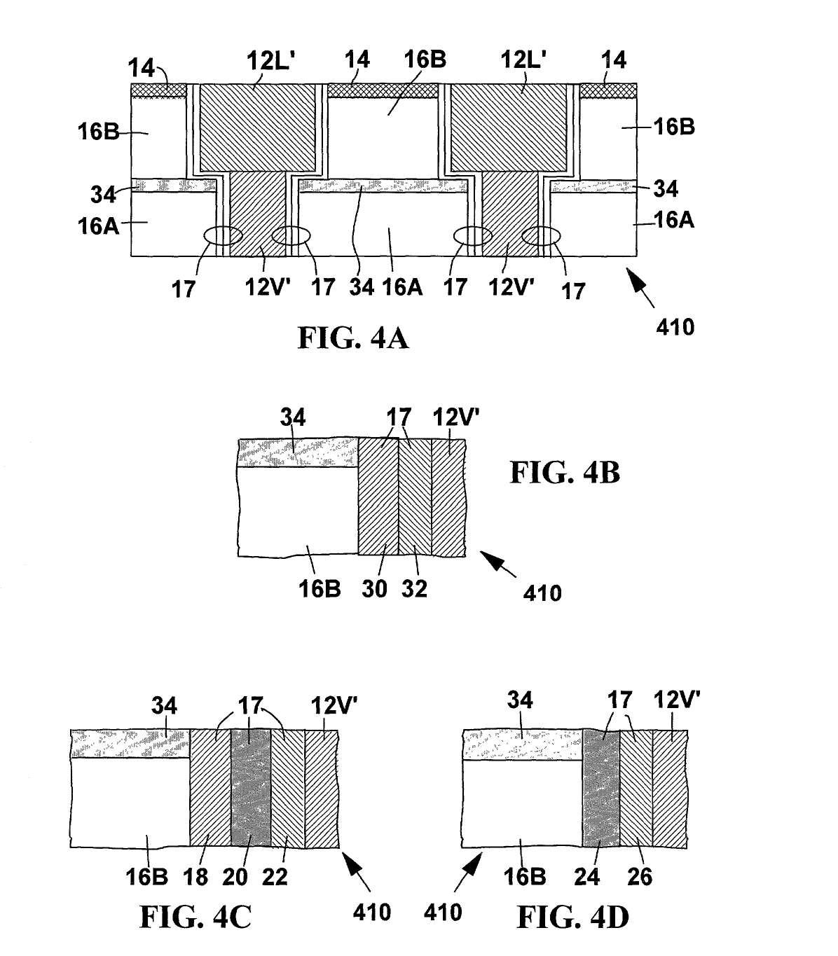

FIGS. 4A-4D show an insulator structure of a semiconductor device 410 illustrating a modification of the embodiment of the present invention shown in FIGS. 3A-3D wherein the device 410 includes vias 12V' (composed of a conductive metal) which are formed generally below the top surface of the buried insulator-getter layer 34, whereas the separately deposited conductor lines 12L' (also composed of a conductive metal) are formed above the vias 12V' and above the level of the buried insulator-getter layer 34. Again, the buried insulator-getter layer 34 is incorporated as a buried insulator 34 at a deep level within the main dielectric layer 16 which is composed of an upper main dielectric layer 16A and a lower main dielectric layer 16B.

FIGS. 5A-5D are a group of drawings of an insulator structure of a semiconductor device 510 illustrating the use of a getter-insulator or dielectric layer post cap 36 (referred to hereinafter as a “sub-main dielectric”) located deep in the device 510 below the main dielectric layer 16 at a level near that of the lower ends of vias 12V.

FIG. 5A is a drawing showing the use of a buried “sub-main dielectric” getter layer 36 as either a sub-main dielectric layer 16 insulator level or a post cap 36 dielectric in combination with the buried cap layer 38. This structure may be optimally used, for example, with layer 36 being a dielectric getter and with layers 38, 36 and 16 deposited sequentially in a single cluster tool (for example a Plasma Enhanced Chemical Vapor Deposition (PE CVD) cluster tool) or a single deposition chamber. One method for maximizing the effectiveness of the gettering action in a structure in accordance with this invention is to employ the concerted deposition of the getter layer followed by a sealing layer to block the environmental contamination of the getter layer—thus maintaining the maximum capacity of the getter layer for the removal of contaminates sealed in the chip during processing by elimination of the potential consumption of getter capacity by environmental exposure. Also, this getter construction may be used when spin-on main dielectric layers 16 are used in device structures in that a pre-deposition of a getter layer 36 may be applied before the main dielectric layer 16.

FIGS. 5B and 5C are analogous to the FIGS. 3B and 3C, where it is illustrated that this “sub-main dielectric” getter layer 36 may or may not be used with a getter liner composite structure.

In the embodiment of FIG. 5B, the metallic liner layers 17 comprise the outer metallic liner layer 30 and inner metallic liner layer 32 without any getter layer. The main dielectric layer 16 is on the left of the outer metallic liner layer 30; and the metal conductor line 12L on the right of the inner metallic liner layer 32. Note that in the case of FIG. 2B neither the outer metallic liner layer 30 nor the inner metallic liner 32 is a getter layer. In this embodiment the only getter layer present is the buried, “sub-main dielectric” getter layer 36 on top of the cap layer 38.

In FIG. 5C the composite structure of the metallic liner 17 includes getter layer 20 between the inner metallic liner layer 22 and the outer metallic liner layer 18 as in FIG. 2C.

In FIG. 5D the composite structure of the metallic liner 17 includes getter layer 24 between the inner metallic liner layer 26 and the main dielectric layer 16 as in FIG. 1C.

### EXAMPLE EMBODIMENTS

Four embodiments are now described, with the getter placed in different locations within the BEOL interconnect structure. The key attributes of the inventive getter film are as follows:

The layer must react with moisture and/or oxygen.

This reaction must be irreversible under the operating conditions of the device. (i.e. once the moisture and/or oxygen has reacted, it is not released, thus, it is removed from the possibility of reacting with other films within the device). This reaction must not produce a product that causes detrimental effects on the device/package. For example, there should be little if any volume expansion, the product should not degrade the established interfaces.

This reaction must not produce mobile by-products which are detrimental to the device.

This reaction product is itself an insulator (Examples I and II). Note that EXAMPLE III, (FIG. 1) does not have to be insulator but could include one. It should be noted that in a metal structure, the getter may become a dielectric during the gettering action. Thus, to avoid resistance problems the getter does not extend into the interface between the contacts at the bottoms of the vias 12V. Examples I, II, and IV (FIGS. 2, 3, 4, 5) require that the insulator getter layer 28/34/36 be an insulator and that the reaction products be insulators.

In accordance with this invention multiple getter films are combined within a device structure for enhanced performance and reliability as follows:

### Example I

In the first inventive example shown above in FIG. 2A, the getter film 28 is a dielectric type getter, and is located between the CMP polish-stop layer 14 and the low-k dielectric layer 16. Thus the getter film 28 is in direct contact with the main dielectric layer 16, and. Specifically, an amorphous hydrogenated silicon carbide (a-SiCH) layer 28 is deposited by PECVD upon the main SiLK™ dielectric.

The dielectric layer 16 can be composed of any low k dielectric material e.g. SiLK™ polymer or a PECVD SiCOH (carbon doped oxide or OrganoSilicate Glass (OSG)) alloy. Examples of these SiCOH or OSG films include Black Diamond (available from Applied Materials) and Coral (available from Novellus), and other products. This invention may use any of various main dielectric materials, including but not limited to, fluorine-doped silicon oxide (called FluoroSilicate Glass (FSG)); spin-on glasses; SilsesQuioxanes, including Hydrogen SilsesQuioxane (HSQ), Methyl SilsesQuioxane (MSQ) and mixtures or copolymers of HSQ and MSQ; and any silicon-containing low-k dielectric. Examples of spin-on low-k films with SiCOH-type composition using SilsesQuioxane chemistry include HOSP™ (available from Honeywell), JSR 5109 and 5108 (available from Japan Synthetic Rubber), Zirkon™ (available from Shipley Microelectronics), and porous low k (ELk) materials (available from Applied Materials)

Optionally, a silicon nitride layer 14 is deposited directly on the amorphous hydrogenated silicon carbide (a-SiCH) getter layer 28, forming a dual hard mask 14.

The silicon nitride layer 14 may be deposited in the same chamber, or in a clustered vacuum tool wherein two to four chambers are connected by a robotic transfer vacuum system. The silicon nitride layer 14 protects the amorphous hydrogenated silicon carbide (a-SiCH) getter (film) layer 28 during processing.

A preferred procedure of integration is deposition by PECVD, in a tool that has a low internal water vapor content. For example, deposition in a PECVD chamber. The preferred getter material is amorphous hydrogenated silicon carbide, specifically containing Si-H bonding which reacts with moisture and/or oxygen.

The content of silicon (Si) and silicon hydride (Si-H) within the amorphous silicon carbide (a-SiCH) may be adjusted for an optimum gettering function concomitantly with optimum dielectric properties.

Examples of other getter materials that may be used in this invention are selected from the group consisting of amorphous hydrogenated silicon carbide (a-SiCH alloys) containing various Si and C contents, amorphous hydrogenated silicon (a-SiH) and, amorphous hydrogenated germanium (a-GeH).

In a preferred example, an amorphous alloy of Si, C, and H that contains a high concentration of SiH₂bonding provides the best material.

### Example II

Example II is similar to Example I, in that the same dielectric getter materials may be used. In Example II, the inventive getter film is not located directly atop the dielectric, and the getter may be placed at any point within the main dielectric layer. See FIG. 3A. The preferred location is at the metal line bottom, where the lines are intersected by connecting vias. Here, the inventive getter also serves as a buried etch stop.

### Example III:

In the third example, a reactive metal getter film composed of Ti, Cr, Al, V, Zr, Hf, and In, or the like, is placed within the conductive metallic diffusion barrier metallic liner that surrounds the Cu (copper) lines. See FIG. 1. In the preferred structure, a reactive first layer comprised of a metal e.g. Ti, Cr, Al, V, Zr, Hf, and In or a suitable metal alloy is deposited in contact with the dielectric. Then, a second less reactive layer (e.g. comprised of Ta, W, Nb or an alloy of these) is deposited.

### Example IV

In the fourth example, as shown in FIG. 5A, a dielectric getter is placed within the post-CMP Cap. The post-CMP Cap is then a bilayer Cap with distributed functions: Cu (copper) barrier and insulator functions in the first lower layer, and getter function in the second film.

Reduction to Practice and Methods of Application:

It is believed by the inventors that an induced level Si-H bonding in a spatially defined matrix (layer or layers within the device), can accomplish these key concepts outlined above. PECVD deposition has been shown to produce a amorphous hydrogenated SiC which has the desired key concepts detailed above and in which the Si and Si-H content can be adjusted by changing the process. Based on our work with the PECVD system we believe that Spin-on siloxane films could be developed for this purpose as well.

Practice in Device Integration

These getter layers can be integrated at many locations within the semiconductor device.

The most desirable method of integration is a deposition in an atmosphere where the moisture content is controlled of this getter layer with a subsequent deposition of a moisture impervious layer to seal this getter inside the device such that its main reaction source of moisture is the trapped moisture sealed within the semiconductor device.

A method of this application is the deposition in a PECVD chamber of an amorphous hydrogenated SiC containing Si-H bonding with a subsequent deposition of a silicon nitride layer preferably by clustered vacuum system techniques.

Another method of application does not require the clustered vacuum techniques and could apply either to spin-on or CVD type application.

This application method would use the temperature sensitivity of the reaction with moisture of a structure in accordance with this invention: such that during the application and subsequent processing of the getter layer, it would not be exposed to a temperature high enough to initiate a sustained chemical reaction until it was sealed within the device by a moisture impervious layer.

In the CMOS integration scheme this would be a SiC layer applied either as a sub-hard mask under the silicon nitride hard mask, a buried hard mask at a point located within the main SiLK™ dielectric, a layer directly subsequent to the silicon nitride capping operation, or just prior to the application of the main SiLK™ dielectric, just before the application of the silicon nitride hard mask. Other main dielectric materials may be used, and separate via level and line level dielectrics (known as a “hybrid” structure) may also be used within this invention

Optimum performance would be achieved in this case by controlling the sequences of elevated temperature exposure such that this getter layer was not exposed to a high reactant concentration of moisture and a high temperature at the same time. A low temperature vacuum degas could be used to desorb moisture before a subsequent high temperature step.

### ADVANTAGES

In the past the main way of addressing the moisture/oxygen problem was to seal the package from outside ingression of moisture once the device processing is complete and by judicious use of vacuum degassing steps in attempts to lower the moisture/oxygen levels within the device package before the application of moisture barrier layers. Both of these methods leave a level of moisture within the sealed package. This invention addresses the problem of the remaining moisture/oxygen by gettering the residual moisture/oxygen, thereby providing a low dielectric constant interconnect structure having enhanced reliability because moisture and/or oxygen is permanently removed from the dielectric by gettering thereof into other compounds which are stable and which are not deleterious.

While this invention has been described in terms of the above specific embodiment(s), those skilled in the art will recognize that the invention can be practiced with modifications within the spirit and scope of the appended claims, i.e. that changes can be made in form and detail, without departing from the spirit and scope of the invention. Accordingly all such changes come within the purview of the present invention and the invention encompasses the subject matter of the claims which follow.

Having thus described the invention, what is claimed as new and desirable to be secured by Letters Patent is as follows:

1. An interconnect structure formed on a substrate comprising:
a main dielectric layer having a top surface,
a cavity formed in the dielectric layer having sidewalls formed therein,
a liner formed on the sidewalls of the cavity forming a narrowed cavity,
a metal conductor formed over the liner in the narrowed cavity, and
a getter layer formed in the structure.

2. The structure of claim 1 wherein the liner comprises laminated layers and the getter layer is formed as one laminated layer in the liner.

3. The structure of claim 1 wherein the liner comprises laminated layers including a barrier layer and a getter layer between the main dielectric and the conductor.

4. The structure of claim 1 wherein the getter layer is formed as a layer in the main dielectric layer.

5. The structure of claim 1 wherein the getter layer is formed as a layer buried in the main dielectric layer.

6. The structure of claim 1 wherein the getter layer is formed as a layer on the surface of the main dielectric layer.

7. The structure of claim 1 wherein the getter layer is formed as a getter dielectric layer buried in the main dielectric layer.

8. The structure of claim 1 wherein the getter layer is formed as a getter dielectric layer on the top surface of the main dielectric layer.

9. The structure of claim 8 comprising:
an integrated circuit with a plurality of patterned metal conductors formed within the main dielectric layer, and
a diffusion barrier cap containing at least a dielectric getter layer deposited directly on the top surface of the main dielectric layer.

10. An interconnect integrated circuit structure comprising:
a main dielectric material with a cavity formed therein lined with a barrier liner,
a patterned metal conductor formed within the barrier liner in the cavity,
the conductor having a top surface, and
a mask patterning/Chemical Mechanical Polishing (CMP) stop layer formed atop the dielectric material.

11. The structure of claim 10 wherein the main dielectric material is selected from the group consisting of an aromatic hydrocarbon thermosetting polymer fluorine-doped silicon oxide, FluoroSilicate Glass (FSG), spin-on glasses; silsesquioxanes, including hydrogen silsesquioxane (HSQ), methyl silsesquioxane (MSQ), and mixtures and copolymers of HSQ and MSQ; silicon-containing low-k dielectric, spin-on low-k films with SiCOH-type composition using silsesquioxane chemistry, and porous low k materials.

12. The structure of claim 10 wherein:
the conductor is surrounded by a conductive metallic diffusion barrier liner 1 nm to 10 nm thick,
the conductive metallic diffusion barrier liner being on all sides except for the top surface of the conductor,
the mask patterning/CMP stop layer comprising an amorphous Si, C, H alloy that reacts with moisture and/or oxygen, and
the mask patterning/CMP stop layer having a top surface that is substantially co-planar with the top surface of the patterned metal conductors.

13. The structure of claim 10 wherein the mask patterning/CMP stop layer is comprised of two regions,
a lower reactive region that reacts with moisture and/or oxygen, and
an upper region that seals and/or protects the lower reactive region from oxidation.

14. The structure of claim 10 wherein the mask patterning/CMP stop layer includes two regions comprising:
a lower region containing a higher concentration of silicon and hydrogen, that reacts with moisture and/or oxygen, and
an upper region that is more dense which contains less hydrogen.

15. The structure of claim 1 comprising:
an interconnect formed in an integrated circuit including the metal conductor formed within the main dielectric layer,
the conductor having a top surface,
the liner comprises a conductive metallic diffusion barrier 1 to 10 nm thick, and
the conductive metallic diffusion barrier includes the getter layer which comprises a reactive metal layer composed of a metal selected from the group consisting of Ti, Cr, Al, V, Zr, Hf, and In.

16. The structure of claim 1 comprising:
an interconnect formed in an integrated circuit including the metal conductor formed within the main dielectric layer,
the conductor having a top surface,
the liner comprises a conductive metallic diffusion barrier 1 to 10 nm thick,
the conductive metallic diffusion barrier includes a layer which comprises a reactive metal layer composed of a metal selected from the group consisting of Ti, Cr, Al, V, Zr, Hf, and In, and
the conductive metallic diffusion barrier includes a less reactive metal selected from the group consisting of Ta, W, Nb and alloys thereof.

17. The structure of claim 1 wherein a dielectric getter layer is formed as a layer buried in the main dielectric layer in contact with the liner and the line includes a conductive getter layer.

18. The structure of claim 1 wherein a dielectric getter layer is formed as a layer buried below the main dielectric layer.

19. The structure of claim 1 wherein the getter layer comprises a material selected from the group consisting of amorphous hydrogenated silicon carbide, a-SiCH alloys, a-SiH and a-GeH.

20. The structure of claim 1 wherein the getter layer comprises a material selected from the group consisting of amorphous hydrogenated silicon carbide, a-SiCH alloys deposited on the top surface of the main dielectric layer.

21. The structure of claim 10 wherein the main dielectric material is comprised of two sublayers, a via dielectric and a line dielectric, and each of these is selected from the group consisting of an aromatic hydrocarbon thermosetting polymer fluorine-doped silicon oxide, FluoroSilicate Glass (FSG), spin-on glasses; silsesquioxanes, including hydrogen silsesquioxane (HSQ), methyl silsesquioxane (MSQ), and mixtures and copolymers of HSQ and MSQ; silicon-containing low-k dielectric, spin-on low-k films with SiCOH-type composition using silsesquioxane chemistry, and porous low k materials.
